(19) United States
(12) Patent Application Publication
(10) Pub. No.: US 2026/0161089 A1
(43) Pub. Date: Jun. 11, 2026

(54) COMPOSITION FOR REMOVING EDGE BEAD FROM METAL CONTAINING RESISTS, AND METHOD AND SYSTEM OF FORMING PATTERNS USING THE SAME

(71) Applicant: SAMSUNG SDI CO., LTD., Yongin-si (KR)

(72) Inventors: Gyeonghun PARK, Suwon-si (KR); Hyungrang MOON, Suwon-si (KR); Si-Kyun PARK, Suwon-si (KR); Jin-Hee BAE, Suwon-si (KR); Seung HAN, Suwon-si (KR); Taeksoo KWAK, Suwon-si (KR); Taeho KIM, Suwon-si (KR); Rosa SHIN, Suwon-si (KR); Jongpil HO, Suwon-si (KR); Minsoo KIM, Suwon-si (KR)

(21) Appl. No.: 19/180,019

(22) Filed: Apr. 15, 2025

(30) Foreign Application Priority Data
Jul. 26, 2024 (KR) 10-2024-0099696

(51) Int. Cl. G03F 7/20; G03F 7/004

(52) U.S. Cl. CPC G03F 7/2028; G03F 7/0042

(57) ABSTRACT

A composition for removing edge beads from a metal-containing resist includes an organic solvent, at least one alcohol-based compound selected from among a diol compound and a cyclic alcohol compound, and an acid compound having pKa1 of 1.0≤pKa1≤4.5. In addition, there is provided a method and a system of forming patterns using the composition.

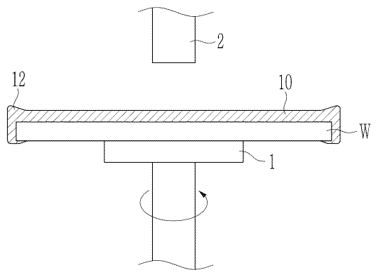

### CROSS-REFERENCE TO RELATED APPLICATION

The present application claims priority to and the benefit of Korean Patent Application No. 10-2024-0099696, filed on Jul. 26, 2024, in the Korean Intellectual Property Office, the entire content of which is incorporated herein by reference.

### BACKGROUND

### 1. Field

One or more embodiments of the present disclosure relate to compositions for removing edge beads from metal-containing resists, and methods and systems of forming patterns using the composition.

### 2. Description of the Related Art

In recent years, the semiconductor manufacturing industry has seen a continuous reduction in critical dimensions. This dimensional reduction necessitates new types (kinds) of high-performance photoresist materials and patterning methods that meet the demand for processing and patterning increasingly smaller features.

Also, with the rapid development of the semiconductor industry, there is a growing need for semiconductor devices with faster operation speeds and larger storage capacities. To meet these requirements, process technologies aimed at improving integration, reliability, and response speed of semiconductor devices are being actively researched and developed. For example, it is crucial (important) to accurately control and implant impurities in the working regions of a semiconductor substrate (e.g., a silicon substrate) and to interconnect these regions to form devices and ultra-high-density integrated circuits. This can be achieved through photolithographic processes, which involve coating a photoresist on the substrate, selectively exposing it to ultraviolet (UV) light (including extreme ultraviolet (EUV)), electron beams, X-rays, and/or the like, and then developing it.

In the process of forming a resist (i.e., photoresist) layer, a resist composition is coated on a substrate (e.g., a semiconductor substrate), typically while rotating the substrate. This process may result in resist being coated on the edge and rear surface of the substrate, potentially causing particles or pattern defects in subsequent semiconductor processes such as etching and ion implantation. Therefore, an edge bead removal (EBR) process is performed to strip and remove the resist from the edge and rear surface of the substrate using a thinner composition. The EBR process requires a composition with excellent or suitable solubility for the resist (photoresist), effectively removing beads and any remaining resist on the substrate without leaving residues.

### SUMMARY

One or more aspects of embodiments of the present disclosure are directed toward a composition for removing edge beads from a metal-containing resist.

One or more aspects of embodiments of the present disclosure are directed toward a method of forming patterns using the composition.

Additional aspects will be set forth in part in the description which follows and, in part, will be apparent from the description, or may be learned by practice of the presented embodiments of the disclosure.

According to one or more embodiments of the present disclosure, a composition for removing edge beads from a metal-containing resist includes an organic solvent, at least one alcohol-based compound selected from among a diol compound and a cyclic alcohol compound, and an acid compound having pKa1 of 1.0≤pka1≤4.5.

According to one or more embodiments of the present disclosure, a method of forming patterns includes coating a metal-containing resist composition on a substrate; coating the composition for removing edge beads from a metal-containing resist along an edge of the substrate; drying and heating a resultant coating to form a metal-containing resist layer on the substrate; and exposing and developing the metal-containing resist layer to form a resist pattern.

According to one or more embodiments of the present disclosure, a system for forming patterns includes: means for coating a metal-containing resist composition on a substrate; means for coating the composition for removing edge beads from a metal-containing resist along an edge of the substrate; means for drying and heating a resultant coating to form a metal-containing resist layer on the substrate; and means for exposing and developing the metal-containing resist layer to form a resist pattern.

The composition for removing edge beads from a metal-containing resist according to one or more embodiments reduces the metal-based contamination inherent in the metal-containing resist and removes the resist coated on the edge and the rear surface of the substrate, thereby satisfying requirements of processing and patterning of smaller features.

### BRIEF DESCRIPTION OF THE DRAWINGS

The accompanying drawing is included to provide a further understanding of the present disclosure and are incorporated in and constitute a part of the present disclosure. The drawing illustrates embodiments of the present disclosure and, together with the description, serve to explain principles of the present disclosure. The above and other aspects, features, and advantages of certain embodiments of the disclosure will be more apparent from the following description taken in conjunction with the accompanying drawings.

The drawing is a schematic view of a photoresist coating apparatus according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, embodiments of the present disclosure are described in more detail with reference to the accompanying drawings. In the following description of the present disclosure, the well-suitable functions or constructions will not be described in order to clarify the present disclosure.

In order to clearly illustrate the present disclosure, the unrelated description and relationships are not provided, and throughout the disclosure, the same or similar configuration elements are designated by the same reference numerals. Also, because the size and thickness of each configuration shown in the drawing are illustratively shown for better understanding and ease of description, the present disclosure is not necessarily limited thereto.

In the drawings, the thickness of layers, films, panels, regions, and/or the like, may be exaggerated for clarity. In the drawings, the thickness of a part of layers or regions, and/or the like, may be exaggerated for clarity. It will be understood that if (e.g., when) an element such as a layer, a film, a region, or a substrate is referred to as being “on” another element, it may be directly on the other element or intervening elements may also be present therebetween. In contrast, when an element is referred to as being “directly on” another element, there are no intervening elements present therebetween.

In the present disclosure, “substituted” refers to replacement of hydrogen by deuterium, a halogen, a hydroxyl group, a thiol group, a cyano group, a carbonyl group, a carboxyl group, an amino group, an amide group, an ester group, a substituted or unsubstituted C1 to C30 amine group, a nitro group, a substituted or unsubstituted C1 to C40 silyl group, a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, or a C1 to C20 sulfide group. “Unsubstituted” refers to that hydrogen remains as hydrogen without being replaced by another substituent.

In the present disclosure, “alkyl group” refers to a linear or branched aliphatic hydrocarbon group, unless otherwise defined. The alkyl group may be a “saturated alkyl group” that does not contain any double or triple bonds.

The alkyl group may be a C1 to C20 alkyl group. For example, the alkyl group may be a C1 to C10 alkyl group or a C1 to C6 alkyl group. For example, a C1 to C5 alkyl group refers to that the alkyl chain contains 1 to 5 carbon atoms, and may be selected from among methyl, ethyl, propyl, iso-propyl, n-butyl, iso-butyl, sec-butyl, t-butyl, n-pentyl, tert-pentyl, neopentyl, isopentyl, sec-pentyl, 3-pentyl, and sec-isopentyl.

Non-limiting examples of the alkyl group may include a methyl group, an ethyl group, a propyl group, an isopropyl group, a butyl group, an isobutyl group, a tert-butyl group, a pentyl group, a hexyl group, and/or the like.

In the chemical formulas described herein, t-butyl refers to a tert-butyl group.

In the present disclosure, if (e.g., when) a definition is not otherwise provided, “cycloalkyl group” refers to a monovalent cyclic aliphatic hydrocarbon group.

The cycloalkyl group refers to a cyclopropyl group, a cyclobutyl group, a cyclopentyl group, or a cyclohexyl group, and/or the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

In the present disclosure, if (e.g., when) a definition is not otherwise provided, “heterocycloalkyl group” refers to a cycloalkyl group including at least one hetero atom selected from among N, O, S, P, and Si.

In the present disclosure, if (e.g., when) a definition is not otherwise provided, “alkenyl group” may be a linear or branched aliphatic hydrocarbon group, and refers to an aliphatic unsaturated alkenyl group containing one or more carbon-carbon double bonds.

In the present disclosure, if (e.g., when) a definition is not otherwise provided, “alkynyl group” may be a linear or branched aliphatic hydrocarbon group, and refers to an unsaturated alkynyl group containing one or more carbon-carbon triple bonds.

In the present disclosure, “aryl group” refers to a substituent in which all elements of a cyclic substituent have p-orbitals, and these p-orbitals form a conjugate and may include monocyclic or fused ring polycyclic (i.e., rings that share adjacent pairs of carbon atoms) functional groups.

For example, “a heteroaryl group” may refer to a aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, each ring may include one to three heteroatoms.

For example, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a (e.g., any suitable) combination thereof, but embodiments of the present disclosure are not limited thereto.

For example, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, or a substituted or unsubstituted dibenzothiophenyl group, a substituted or unsubstituted benzonaphthofuranyl group, a substituted or unsubstituted benzonaphthothiophenyl group, a substituted or unsubstituted benzofuranofluorenyl group, a substituted or unsubstituted benzothienofluorenyl group, or a (e.g., any suitable) combination thereof, but embodiments of the present disclosure are not limited thereto.

The drawing is a schematic view showing a photoresist coating apparatus according to one or more embodiments of the present disclosure.

Referring to the drawing, a substrate support portion 1 on which a substrate W is placed is equipped therewith, and the substrate support portion 1 includes a spin chuck or a spin coater.

The substrate support portion 1 rotates in a first direction at a set or predetermined rotation speed to provide a centrifugal force to the substrate W. A spray nozzle 2 may be arranged on the substrate support portion 1, and the spray nozzle 2 may be arranged in an air region away from an upper portion of the substrate W and moves toward the upper portion of the substrate during a solution supply stage to spray a photoresist solution 10. Accordingly, the photoresist solution 10 is coated on a surface (e.g., an upper surface) of the substrate W by the centrifugal force. Herein, the photoresist solution 10 supplied to the center of the substrate W is coated while spreading to the edge of the substrate W by the centrifugal force, wherein a portion of photoresist solution 10 moves to side surfaces of the substrate W and a lower surface of the edge of the substrate.

For example, in one or more embodiments, in the coating process, the photoresist solution 10 may be coated mainly in a spin coating method, wherein a set or predetermined amount of the photoresist solution 10 with viscosity is supplied to a center portion of the substrate W and gradually spreads toward the edge of the substrate W by the centrifugal force.

Accordingly, a resist layer is evenly formed by a rotational speed of the substrate support portion.

In one or more embodiments, this rotation evaporates a solvent from the photoresist solution and thereby gradually increases the viscosity, resulting in making a relatively large amount of the photoresist accumulated on the edge of the substrate by the action of surface tension and, severely, even onto the lower surface of the edge of the substrate, which is referred to as edge beads 12 in the present disclosure.

Hereinafter, a composition for removing edge beads from a metal-containing resist according to one or more embodiments will be described in more detail. In the present disclosure, unless otherwise provided, the term “resist” may be interchangeable with the term “photoresist.”

The composition for removing edge beads from a metal-containing resist according to one or more embodiments of the present disclosure may include an organic solvent, at least one alcohol-based compound selected from among a diol compound and a cyclic alcohol compound, and an acid compound having pKa1 of 1.0≤pKa1≤4.5.

The composition for removing edge beads from a metal-containing resist may include a cyclic compound substituted with a hydroxyl group (—OH), and because the hydroxyl group (—OH) forms a coordination bond with the metal-containing resist, the metal-containing resist may be effectively removed by applying the composition containing the same.

In one or more embodiments, the diol compound may be represented by Chemical Formula 1 or Chemical Formula 2.

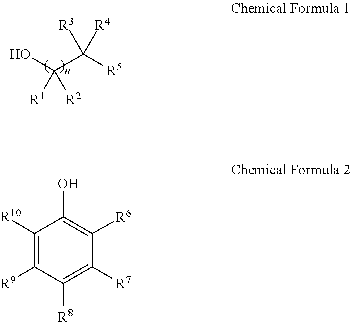

In Chemical Formula 1 and Chemical Formula 2,

R¹ to R¹⁰ may each independently be hydrogen, a halogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group,
one selected from among R¹ to R⁵ is a hydroxyl group,
one selected from among R⁶ to R¹⁰ is a hydroxyl group, and
n may be an integer of 1 to 10.

In one or more embodiments, the diol compound represented by Chemical Formula 1 may be represented by Chemical Formula 1-1.

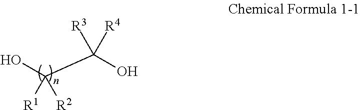

In one or more embodiments, the diol compound represented by Chemical Formula 2 may be represented by any one selected from among Chemical Formulas 2-1 to 2-3.

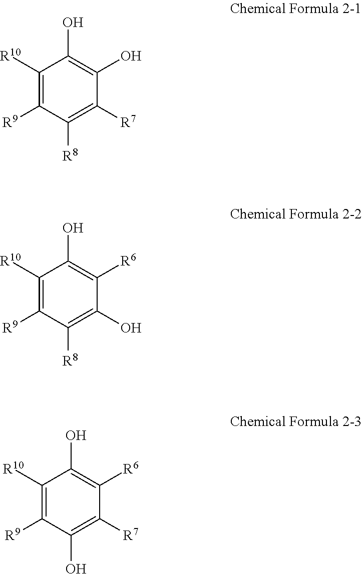

In Chemical Formula 1-1 and Chemical Formula 2-1 to Chemical Formula 2-3,

the definitions of R¹ to R⁴, R⁶ to R¹⁰, and n may each independently be the same as described herein.

In one or more embodiments, the cyclic alcohol compound may be represented by Chemical Formula 3.

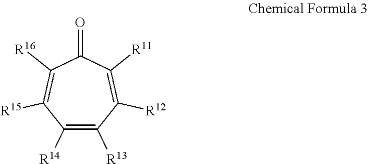

In Chemical Formula 3,
R¹¹ to R¹⁶ may each independently be hydrogen, a halogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group, and
at least one selected from among R¹¹ to R¹⁶ is a hydroxyl group.

In one or more embodiments, the cyclic alcohol compound represented by Chemical Formula 3 may be represented by any one selected from among Chemical Formula 3-1 to Chemical Formula 3-3.

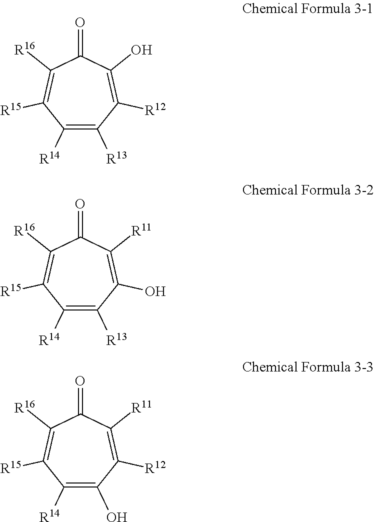

In Chemical Formula 3-1 to Chemical Formula 3-3,
the definitions of R¹¹ to R¹⁶ may each independently be the same as described herein.

In one or more embodiments, the alcohol-based compound may include (e.g., be) at least one of pyrocatechol, 4-methylcatechol, 4-chlorocatechol, 4-nitrocatechol, tropolone, 1,2-ethanediol, and/or a (e.g., any suitable) combination thereof.

In one or more embodiments, the pKa1 of the acid compound may be 1.0≤pKa1≤4.0.

The acid compound may be at least one of phosphoric acid, phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, 6-hydroxyhexyl phosphonic acid, decyl phosphonic acid, methylene diphosphonic acid, nitrilotrimethylene triphosphonic acid, diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, chloroacetic acid, formic acid, acetic acid, or a (e.g., any suitable) combination thereof.

In one or more embodiments, the acid compound may be at least one of phosphoric acid, phosphonic acid, methyl phosphonic acid, butyl phosphonic acid, phenyl phosphonic acid, vinyl phosphonic acid, chloroacetic acid, formic acid, acetic acid, or a (e.g., any suitable) combination thereof.

In one or more embodiments, the composition for removing edge beads from a metal-containing resist may include: about 0.05 to about 40 wt % of the alcohol-based compound and the acid compound; and about 60 to about 99.95 wt % of the organic solvent, based on a total weight of 100 wt % of the composition.

Within the above range, the alcohol-based compound and the acid compound may be included in an amount of about 0.1 to about 40 wt %, for example, about 0.5 to about 40 wt % or about 1 to about 40 wt %.

The alcohol-based compound and the acid compound may be included in a weight ratio of about 1:0.5 to about 1:50.

For example, in one or more embodiments, the alcohol-based compound and the acid compound may be included in a weight ratio of about 1:1 to about 1:50, for example, in a weight ratio of about 1:1 to about 1:40 or about 1:1 to about 1:30.

Within the above range, the alcohol-based compound may be included in an amount of less than about 10 wt %, for example, in an amount of less than about 9 wt %, or in an amount of less than about 8 wt %.

Within the above range, the acid compound may be included in an amount of less than about 40 wt %, for example, in an amount of less than or equal to about 35 wt %, or in an amount of less than or equal to about 30 wt %.

Non-limiting examples of the organic solvent included in the composition for removing edge beads from a metal-containing resist according to one or more embodiments may include propylene glycol methyl ether (PGME), propylene glycol methyl ether acetate (PGMEA), propylene glycol butyl ether (PGBE), ethylene glycol methyl ether, diethyl glycol ethyl methyl ether, dipropyl glycol dimethyl ether, ethanol, 2-butoxyethanol, n-propanol, isopropanol, n-butanol, isobutyl alcohol, hexanol, ethylene glycol, propylene glycol, heptanone, propylene carbonate, butylene carbonate, diethyl ether, dibutyl ether, ethyl acetate, methyl 3-methoxypropionate, ethyl 3-ethoxypropionate, diisopentyl ether, xylene, acetone, methyl ethyl ketone, methyl isobutyl ketone, tetrahydrofuran, dimethyl sulfoxide, dimethylformamide, acetonitrile, diacetone alcohol, 3,3-dimethyl-2-butanone, N-methyl-2-pyrrolidone, dimethylacetamide, cyclohexanone, methyl-2-hydroxy-2-methylpropanoate (HBM), gamma butyrolactone (GBL), 1-butanol, ethyl lactate (EL), diene butyl ether (DBE), diisopropyl ether (DIAE), acetylacetone, 4-methyl-2-pentanol (also may be described as methyl isobutyl carbinol (MIBC)), 1-methoxy-2-propanol, 1-ethoxy-2-propanol, toluene, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, butyl lactate, methyl 2-hydroxyisobutyrate, methoxybenzene, n-butyl acetate, 1-methoxy-2-propyl acetate, methoxyethoxy propionate, ethoxyethoxypropionate, and/or a (e.g., any suitable) mixture thereof.

The composition for removing edge beads from a metal-containing resist according to one or more embodiments of the present disclosure may be effective in removing metal-containing resists, for example, undesired metal residues, such as tin-based metal residues.

In the case (e.g., embodiments) of including other additives, the organic solvent may be included in a balance amount excluding the included components other than the organic solvent.

In one or more embodiments, the composition may further include at least one other additive selected from among a surfactant, a dispersant, a moisture absorbent, and a coupling agent.

According to one or more embodiments of the present disclosure, a method of forming patterns may include removing edge beads utilizing the composition for removing edge beads from a metal-containing resist. For example, in one or more embodiments, the manufactured/formed pattern may be a photoresist pattern. In one or more embodiments, it may be a negative-type (kind) photoresist pattern.

The method of forming patterns according to one or more embodiments may include coating a metal-containing resist composition on a substrate, coating (e.g., applying) the composition for removing edge beads from a metal-containing resist along an edge of the substrate, drying and heating a resultant coating to form a metal-containing resist layer on the substrate, and exposing and developing the metal-containing resist layer to form a resist pattern.

For example, the forming of patterns utilizing the metal-containing resist composition may include coating the metal-containing resist composition on the substrate on which a thin film is formed by spin coating, slit coating, inkjet printing, and/or the like, and drying the coated metal-containing resist composition to form a photoresist layer. The metal-containing resist composition may include a tin-based compound, and for example, the tin-based compound may include at least one of an organic oxy group-containing tin compound or an organic carbonyloxy group-containing tin compound.

For example, in one or more embodiments, the metal compound included in the metal-containing resist composition may be represented by Chemical Formula 4.

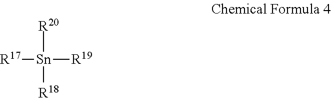

In Chemical Formula 4,
R¹⁷ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R¹⁸ to R²⁰ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylthio or arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), and
at least one selected from among R¹⁸ to R²⁰ is selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an amidinato group (—NR^{h}C(NRⁱ) R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), an alkylthio or arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof).

In one or more embodiments, the metal compound included in the metal-containing resist composition may be represented by Chemical Formula 5 or Chemical Formula 6.

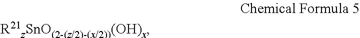

In Chemical Formula 5,
R²¹ may be a C1 to C31 hydrocarbyl group, 0<z≤2, and 0<(z+x)≤4;

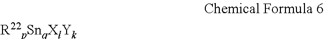

In Chemical Formula 6,
R²² may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a (e.g., any suitable) combination thereof,
X may be sulfur(S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof,
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and
p, q, l, and k may each independently be an integer of 1 to 20.

In one or more embodiments, the composition for removing edge beads from a metal-containing resist along the edge of the substrate may be coated (e.g., applied) while rotating the substrate at an appropriate or suitable speed (e.g., 500 revolutions per minute (rpm) or more).

Subsequently, a first heat treatment process of heating the substrate on which the resist layer is formed is performed. The first heat treatment process may be performed at a temperature of about 80° C. to about 120° C., and in this process, the solvent is evaporated and the resist layer may be more firmly adhered to the substrate.

Then, the resist layer is selectively exposed.

For example, examples of light that may be used in the exposure process may include not only light such as i-line (wavelength 365 nanometers (nm)), KrF excimer laser (wavelength 248 nm), or ArF excimer laser (wavelength 193 nm), but also EUV (light having a high energy wavelength such as EUV (Extreme UltraViolet, wavelength 13.5 nm), E-Beam (electron beam), and/or the like.

For example, the light for exposure according to one or more embodiments may be light having a wavelength range of about 5 nm to about 150 nm, or light having a high energy wavelength such as EUV (Extreme UltraViolet, wavelength 13.5 nm), or E-Beam (electron beam), and/or the like.

In the forming of the resist pattern, a negative-type (kind) pattern may be formed.

The exposed region of the resist layer has a solubility different from that of the unexposed region of the resist layer as a polymer is formed in the exposed region by a crosslinking reaction such as condensation between organometallic compounds.

Then, a second heat treatment process is performed on the substrate. The second heat treatment process may be performed at a temperature of about 90° C. to about 200° C. By performing the second heat treatment process, the exposed region of the resist layer becomes difficult to be dissolved in a developer.

For example, in one or more embodiments, the photoresist pattern corresponding to a negative tone image may be completed by dissolving and removing the resist layer corresponding to the unexposed region using an organic solvent such as 2-heptanone.

The developer used in the in the method of forming patterns according to one or more embodiments may be an organic solvent, and non-limiting examples thereof may include ketones such as methyl ethyl ketone, acetone, cyclohexanone, and/or 2-heptanone, alcohols such as 4-methyl-2-propanol, 1-butanol, isopropanol, 1-propanol, and/or methanol, esters such as propylene glycol monomethyl ether acetate, ethyl acetate, ethyl lactate, n-butyl acetate, butyrolactone, aromatic compounds such as benzene, xylene, and/or toluene, and/or a (e.g., any suitable) combination thereof.

In one or more embodiments, the method of forming patterns may further include coating (e.g., applying) the composition for removing edge beads from a metal-containing resist after the exposure and development processes. For example, in one or more embodiments, it may include coating (e.g., applying) an appropriate or suitable amount of the composition for removing edge beads from a metal-containing resist along the edge of the substrate while rotating the substrate at an appropriate or suitable speed (e.g., 500 rpm or more).

As described above, the photoresist pattern formed by exposure to light having a wavelength such as i-line (wavelength 365 nm), KrF excimer laser (wavelength 248 nm), ArF excimer laser (wavelength 193 nm), or EUV (Extreme UltraViolet; wavelength 13.5 nm), or light having high energy such as an E-beam (electron beam) may have a thickness width of about 5 nm to about 100 nm. For example, in one or more embodiments, the photoresist pattern may be formed to have a thickness width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern may have a pitch having a half-pitch of less than or equal to about 50 nm, for example less than or equal to 40 nm, for example less than or equal to 30 nm, for example less than or equal to 20 nm, or for example less than or equal to 15 nm and a line width roughness of less than or equal to about 10 nm, less than or equal to about 5 nm, less than or equal to about 3 nm, or less than or equal to about 2 nm.

Hereinafter, the present disclosure will be described in more detail through examples relating to the preparation of the composition for removing edge beads from a metal-containing resist. However, the technical features of the present disclosure are not limited by the following examples.

### Preparation Example: Preparation of Photoresist Compositions Including Organometallic Compound

An organometallic compound having a structural unit of Chemical Formula C was dissolved in 4-methyl-2-pentanol at a concentration of 1 wt %, and then filtered through a 0.1 μm PTFE syringe filter to prepare a photoresist composition.

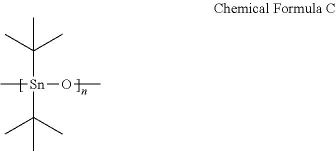

### Examples and Comparative Examples: Preparation of Compositions for Removing Edge Beads

The alcohol-based compound, acid compound, and organic solvent were mixed according to the compositions shown in Table 1, then stirred at room temperature (25° C.) to completely dissolve. Afterwards, the final composition was obtained by passing it through a PTFE material filter having a pore size of 1 μm.

TABLE 1

| | | | | Alcohol-based |
|---|---|---|---|---|
| | Organic | Acid compound | | compound |
| | solvent | (wt %) | pKa1 | (wt %) |
| Example 1 | PEP | methyl | 2.4 | pyrocatechol |
| | | phosphonic acid | | (2 wt %) |
| | | (10 wt %) | | |
| Example 2 | MIBC | butyl phosphonic | 2.6 | 4-methylcatechol |
| | | acid | | (5 wt %) |
| | | (5 wt %) | | |
| Example 3 | PGMEA | phenyl | 1.8 | 4-chlorocatechol |
| | | phosphonic acid | | (1 wt %) |
| | | (3 wt %) | | |
| Example 4 | MIBC | vinyl phosphonic | 2.1 | tropolone |
| | | acid | | (1 wt %) |
| | | (1 wt %) | | |
| Example 5 | PGMEA | phosphoric acid | 2.2 | 4-nitrocatechol |
| | | (20 wt %) | | (5 wt %) |
| Example 6 | PEP | butyl phosphonic | 2.6 | 1,2-ethanediol |
| | | acid | | (5 wt %) |
| | | (25 wt %) | | |
| Example 7 | PGMEA | phosphonic acid | 1.3 | 4-chlorocatechol |
| | | (20 wt %) | | (5 wt %) |
| Example 8 | PGMEA | chloroacetic acid | 2.9 | pyrocatechol |
| | | (20 wt %) | | (2 wt %) |
| Example 9 | PGMEA | formic acid | 3.8 | 4-nitrocatechol |
| | | (30 wt %) | | (1 wt %) |
| Comparative | PEP | — | — | glycerol |
| Example 1 | | | | (2 wt %) |
| Comparative | PEP | butyl phosphonic | 2.6 | — |
| Example 2 | | acid | | |
| | | (5 wt %) | | |
| Comparative | PGMEA | methyl | 2.4 | isopropanol |
| Example 3 | | phosphonic acid | | (2 wt %) |
| | | (10 wt %) | | |
| Comparative | PGMEA | phosphoric acid | 2.2 | — |
| Example 4 | | (20 wt %) | | |
| Comparative | PGMEA | acetic acid | 4.8 | — |
| Example 5 | | (40 wt %) | | |

* PGMEA: propylene glycol methylether acetate
* PGME: propylene glycol methylether
* MIBC: methyl isobutyl carbinol
* PEP: (PGMEA:PGME = 7:3 (w/w)) mixed solvent

### Evaluation 1: Evaluation of Residual Film Thickness (Strip Test) and Evaluation of Sn Residual Amount Before Development

1.0 mL of the photoresist composition including an organometallic compound according to Preparation Example was poured onto a 6-inch silicon wafer, allowed to stand for 20 seconds, and then spin-coated at a speed of 800 rpm for 30 seconds. Then, a resist layer obtained by heat treatment at 200° C. for 60 seconds was subjected to thickness measurement using an ellipsometry method. On a silicon wafer having a resist layer formed thereon, 10 mL of one of the compositions for removing edge beads prepared from Examples 1 to 9 and Comparative Examples 1 to 5 was injected along the edge, spin-coated for 5 seconds, and then dried while rotating at a speed of 1,500 rpm. Then, the thickness of the film obtained by heat treatment at 150° C. for 60 seconds was re-measured using the ellipsometry method to confirm a thickness change before and after the edge bead removal process and evaluated based on the following criteria. In addition, vapor phase decomposition-inductively coupled plasma-mass spectrometry (VPD ICP-MS) analysis was performed to confirm an Sn residual amount, and the results are shown in Table 2.
*
If the residual thickness is less than 5 angstroms (Å): ∘;
if the residual thickness is more than 5 Å: X

### Evaluation 2: Visual Evaluation of Back Stain

The surface stains of the wafer coated with a resist layer after undergoing an edge bead removal process as in Evaluation 1 were checked using the KMAC-ST400DLX equipment, and at the same time, the stains on the back side of the substrate were checked with naked eyes before and after the final baking at 150° C. for 60 seconds. The evaluation criteria are as follows:
*
No stains before/after baking: ∘;
Stains remain but disappear after baking: Δ;
Stains after baking: X

TABLE 2

| | Naked eye | | Residual Sn content |
|---|---|---|---|
| | evaluation | Strip | (e.g., amount) (×10¹⁰ |
| | (surface stain) | test | atoms/cm²) |
| Example 1 | ◯ | ◯ | 9538 |
| Example 2 | ◯ | ◯ | 7769 |
| Example 3 | ◯ | ◯ | 12692 |
| Example 4 | ◯ | ◯ | 6308 |
| Example 5 | ◯ | ◯ | 13769 |
| Example 6 | ◯ | ◯ | 10846 |
| Example 7 | ◯ | ◯ | 8538 |
| Example 8 | ◯ | ◯ | 11846 |
| Example 9 | ◯ | ◯ | 11308 |
| Comparative | ◯ | X | 51500 |
| Example 1 | | | |
| Comparative | X | X | 29600 |
| Example 2 | | | |
| Comparative | X | X | 32500 |
| Example 3 | | | |
| Comparative | ◯ | ◯ | 22000 |
| Example 4 | | | |
| Comparative | ◯ | ◯ | 22600 |
| Example 5 | | | |

Referring to Table 2, the compositions for removing edge beads from a metal-containing resist according to Examples have a superior metal removal effect compared to the compositions for removing edge beads from a metal-containing resist according to Comparative Examples, thereby further promoting the reduction of residual metal.

Herein, it should be understood that terms such as “comprise(s),” “include(s),” or “have/has” are intended to designate the presence of an embodied feature, number, step, element, or a combination thereof, but it does not preclude the possibility of the presence or addition of one or more other features, number, step, element, or a combination thereof.

In the context of the present disclosure and unless otherwise defined, the terms “use,” “using,” and “used” may be considered synonymous with the terms “utilize,” “utilizing,” and “utilized,” respectively.

As utilized herein, the singular forms “a,” “an,” and “the” are intended to include the plural forms as well, unless the context clearly indicates otherwise. Further, the utilization of “may” when describing embodiments of the present disclosure may refer to “one or more embodiments of the present disclosure”. Further, as used herein, the term “and/or” includes any and all combinations of one or more of the associated listed items. The “/” utilized herein may be interpreted as “and” or as “or” depending on the situation. Expressions such as “at least one of,” “one of,” and “selected from,” when preceding a list of elements, modify the entire list of elements and do not modify the individual elements of the list. For example, “at least one of a, b, or c”, “at least one of a, b, and/or c”, “at least one selected from a, b, and c”, “at least one selected from among a to c”, etc. may indicate only a, only b, only c, both (e.g., simultaneously) a and b, both (e.g., simultaneously) a and c, both (e.g., simultaneously) b and c, all of a, b, and c, or variations thereof.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the terms “substantially,” “about,” and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A patten forming system or device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinbefore, the certain embodiments have been described and illustrated, however, it is apparent to a person with ordinary skill in the art that the present disclosure is not limited to the example embodiments as described, and may be variously modified and transformed without departing from the spirit and scope of the present disclosure. Accordingly, the modified or transformed embodiments as such may not be understood separately from the technical ideas and aspects of the disclosure, and the modified embodiments are within the scope of the claims of the disclosure and equivalents thereof.

Reference Numerals and Reference Letters

| | |
|---|---|
| 1: substrate support portion | 2: spray nozzle |
| 10: photoresist solution | 12: edge bead |
| W: substrate | |

What is claimed is:

1. A composition, comprising:
an organic solvent;
one or more alcohol-based compounds selected from among a diol compound and a cyclic alcohol compound; and
an acid compound having pKa1 of 1.0≤pKa1≤4.5,
wherein the composition is a composition for removing edge beads from a metal-containing resist.

2. The composition as claimed in claim 1, wherein
the diol compound is represented by Chemical Formula 1 or Chemical Formula 2: 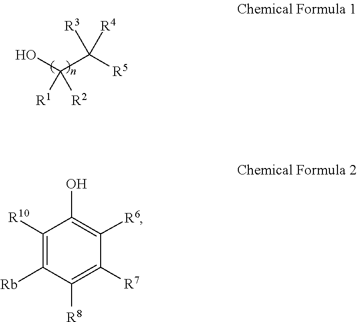
in Chemical Formula 1 and Chemical Formula 2,
R¹ to R¹⁰ being each independently hydrogen, a halogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group,
one selected from among R¹ to R⁵ being a hydroxyl group,
one selected from among R⁶ to R¹⁰ being a hydroxyl group, and
n being an integer of 1 to 10.

3. The composition as claimed in claim 2, wherein
the diol compound represented by Chemical Formula 1 is represented by Chemical Formula 1-1, and
the diol compound represented by Chemical Formula 2 is represented by any one selected from among Chemical Formula 2-1 to 2-3: 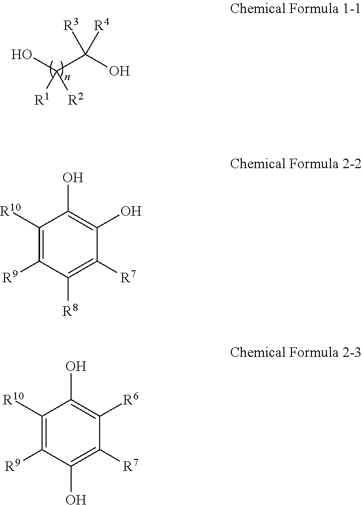
in Chemical Formula 1-1 and Chemical Formula 2-1 to Chemical Formula 2-3,
R¹ to R⁴ and n being each the same as defined in Formula 1, and
R⁶ to R¹⁰ being each the same as defined in Formula 2.

4. The composition as claimed in claim 1, wherein
the cyclic alcohol compound is represented by Chemical Formula 3: 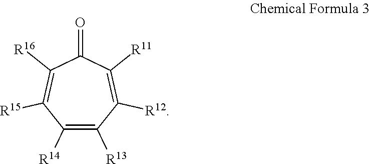
in Chemical Formula 3,
R¹¹ to R¹⁶ being each independently hydrogen, a halogen, a hydroxyl group, an amino group, a nitro group, a substituted or unsubstituted C1 to C30 amine group, a substituted or unsubstituted C1 to C10 alkyl group, or a substituted or unsubstituted C6 to C20 aryl group, and
at least one selected from among R¹¹ to R¹⁶ being a hydroxyl group.

5. The composition as claimed in claim 4, wherein
the cyclic alcohol compound represented by Chemical Formula 3 is represented by any one selected from among Chemical Formula 3-1 to Chemical Formula 3-3: 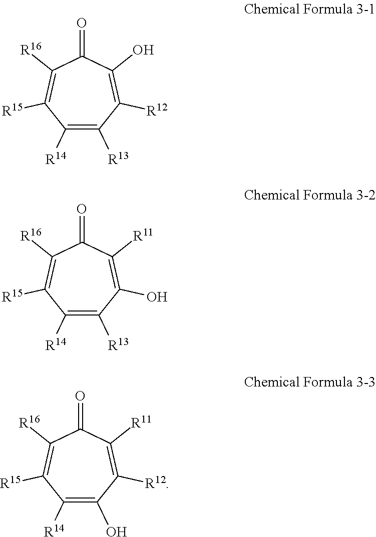
in Chemical Formula 3-1 to Chemical Formula 3-3,
R¹¹ to R¹⁶ being each the same as defined in Formula 3.

6. The composition as claimed in claim 1, wherein
the alcohol-based compound comprises at least one of pyrocatechol, 4-methylcatechol, 4-chlorocatechol, 4-nitrocatechol, tropolone, 1,2-ethanediol, or a combination thereof.

7. The composition as claimed in claim 1, wherein
the pKa1 of the acid compound is 1.0≤pKa1≤4.0.

8. The composition as claimed in claim 1, wherein
the acid compound comprises at least one of phosphoric acid, phosphonic acid, methyl phosphonic acid, ethyl phosphonic acid, butyl phosphonic acid, hexyl phosphonic acid, n-octyl phosphonic acid, tetradecyl phosphonic acid, octadecyl phosphonic acid, phenyl phosphonic acid, vinyl phosphonic acid, 6-hydroxyhexyl phosphonic acid, decyl phosphonic acid, methylene diphosphonic acid, nitrilotrimethylene triphosphonic acid, diphenylphosphinic acid, bis(4-methoxyphenyl) phosphinic acid, phosphinic acid, bis(hydroxymethyl)phosphinic acid, phenylphosphinic acid, p-(3-aminopropyl)-p-butylphosphinic acid, chloroacetic acid, formic acid, acetic acid, or a combination thereof.

9. The composition as claimed in claim 1, wherein
the alcohol-based compound and the acid compound is about 0.05 to about 40 wt % based on a total weight of 100 wt % of the composition, and
the organic solvent is about 60 to about 99.95 wt % based on the total weight of 100 wt % of the composition.

10. The composition as claimed in claim 1, wherein
the alcohol-based compound and the acid compound are in a weight ratio of about 1:0.5 to about 1:50.

11. The composition as claimed in claim 1, wherein
the metal-containing resist comprises one or more tin compounds selected from among an organic oxy group-containing tin compound and an organic carbonyloxy group-containing tin compound.

12. The composition as claimed in claim 11, wherein
the tin compound is represented by Chemical Formula 4: 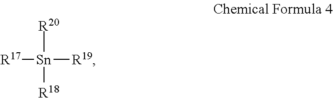
and
wherein, in Chemical Formula 4,
R¹⁷ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R¹⁸ to R²⁰ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R¹⁸ to R²⁰ is selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

13. The composition as claimed in claim 11, wherein
the tin compound is represented by Chemical Formula 5 or Chemical Formula 6: 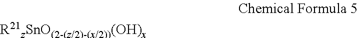
wherein, in Chemical Formula 5,
R²¹ is a C1 to C31 hydrocarbyl group, 0<z≤2, and 0<(z+x)≤4; and 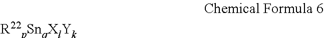
wherein, in Chemical Formula 6,
R²² is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur, selenium, or tellurium,
Y is —OR^{m} or —OC(═O)Rⁿ,
wherein R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
p, q, l, and k are each independently an integer of 1 to 20.

14. A method comprising:
coating a metal-containing resist composition on a substrate;
coating the composition of claim 1 along an edge of the substrate;
drying and heating a resultant coating to form a metal-containing resist layer on the substrate; and
exposing and developing the metal-containing resist layer to form a resist pattern,
wherein the method is a method of forming patterns.

15. A system comprising
means for coating a metal-containing resist composition on a substrate;
means for coating the composition of claim 1 along an edge of the substrate;
means for drying and heating a resultant coating to form a metal-containing resist layer on the substrate; and
means for exposing and developing the metal-containing resist layer to form a resist pattern,
wherein the system is a system for forming patterns.
